(19) United States
(12) Patent Application Publication
(10) Pub. No.: US 2014/0342477 A1
(43) Pub. Date: Nov. 20, 2014

(54) METHOD OF MONITORING SEMICONDUCTOR FABRICATION PROCESS USING XPS

(71) Applicant: Samsung Electronics Co., Ltd., Suwon-Si (KR)

(72) Inventors: Choon-Shik LEEM, Seoul (KR); Deok-Yong KIM, Gunpo-si (KR); Sang-Ho SONG, Seoul (KR); Chul-Gi SONG, Yongin-si (KR); Ho-Yeol LEE, Seoul (KR); Soo-Bok CHIN, Seoul (KR)

(73) Assignee: SAMSUNG ELECTRONICS CO., LTD., Suwon-Si (KR)

(21) Appl. No.: 14/196,184

(22) Filed: Mar. 4, 2014

(30) Foreign Application Priority Data
May 20, 2013 (KR) 10-2013-0056623

(51) Int. Cl. H01L 21/66

(52) U.S. Cl. CPC H01L 22/12
USPC 438/16

(57) ABSTRACT

A method of monitoring a semiconductor fabrication process including forming a barrier pattern on a substrate, forming a sacrificial pattern on the barrier pattern, removing the sacrificial pattern to expose a surface of the barrier pattern, generating photoelectrons by irradiating X-rays to a surface of the substrate, and inferring at least one material existing on the surface of the substrate by collecting and analyzing the photoelectrons may be provided.

### CROSS-REFERENCE TO RELATED APPLICATION

This application claims priority under 35 U.S.C. §119 to Korean Patent Application No. 10-2013-0056623 filed on May 20, 2013, the disclosure of which is hereby incorporated by reference in its entirety.

### BACKGROUND

1. Field

Some example embodiments of the inventive concepts relate to methods of monitoring a semiconductor fabrication process using X-ray photoelectron spectroscopy (XPS).

2. Description of Related Art

In general, an optical monitoring method using light and an electron beam monitoring method using an electron beam have been employed to monitor a semiconductor fabrication process. However, with the optical monitoring method it is difficult to precisely monitor the semiconductor fabrication process due to a limitation of resolution, and with the electron beam monitoring method it is difficult to analyze all types of defects. In particular, because a sample is etched, with the electron beam monitoring method it is difficult to monitor, for instance, an area at which a trench is formed.

### SUMMARY

At least one example embodiment of the inventive concepts provides a method of monitoring a semiconductor fabrication process using X-ray photoelectron spectroscopy (XPS).

At least one example embodiment of the inventive concepts also provides a method of monitoring a semiconductor fabrication process without destroying a wafer in an in-line process.

Example embodiments of the inventive concepts are not limited to the above disclosure, but various other example embodiments may be derived by those of ordinary skill in the art based on the following descriptions.

In accordance with an aspect of the inventive concepts, a method of monitoring a semiconductor fabrication process includes forming a barrier pattern on a substrate, forming a sacrificial pattern on the barrier pattern, removing the sacrificial pattern to expose a surface of the barrier pattern, generating photoelectrons by irradiating X-rays to a surface of the substrate; and inferring at least one material existing on the surface of the substrate by collecting and analyzing the photoelectrons.

When the sacrificial pattern includes silicon, and the barrier pattern includes a transition metal, the material existing on the surface of the substrate may include at least one of fluoride ions (F⁻) and a halogenated metal.

The transition metal may include titanium (Ti), and the halogenated metal may include titanium-fluorine (Ti—F).

The analyzing of the photoelectrons may include measuring intensities of photoelectrons of 1s orbital of halogen element in the halogenated metal.

When the inferring determines that the material consists essentially of the fluoride ions (F−), the inferring further determines that the removing does not completely remove the sacrificial pattern on the barrier pattern.

When the inferring determines that the material includes the fluoride ions (F−) and a Ti—F compound, the inferring further determines that the removing substantially completely removes the sacrificial pattern on the barrier pattern.

The analyzing of the photoelectrons may include: obtaining intensity spectra of the collected photoelectrons; and separating the intensity spectra into at least one individual intensity spectrum according to binding energies of the photoelectrons.

The binding energies may be binding energies of is orbital of the material existing on the surface of the substrate.

Before the forming of the barrier pattern, the method may further include forming a buffer insulating pattern on the substrate, and forming a gate insulating pattern on the buffer insulating pattern.

The buffer insulating pattern may include oxidized silicon, and the gate insulating pattern may include metal oxide.

After the forming of the sacrificial pattern, the method may further include forming a gate spacer that covers a top surface of the sacrificial pattern, side surfaces of the buffer insulating pattern, the gate insulating pattern, the barrier pattern, and the sacrificial pattern, and exposing the top surface of the sacrificial pattern by removing the gate spacer that covers the top surface of the sacrificial pattern.

The gate spacer may include silicon nitride, and the removing of the gate spacer may include performing a chemical-mechanical polishing (CMP) process.

In accordance with another aspect of the inventive concepts, a method of monitoring a semiconductor fabrication process includes introducing a wafer onto a stage of a processing system, a surface of the wafer having at least one halogenated material thereon, the processing system including a chamber, a stage disposed in the chamber, an X-ray source, and a photoelectron detector disposed over the chamber, irradiating X-rays onto the surface of the wafer on the stage using the X-ray source, collecting photoelectrons generated by the halogenated material on the surface of the wafer using the photoelectron detector, and inferring the halogenated material existing on the surface of the wafer by analyzing the collected photoelectrons according to binding energies of 1s orbital of at least one halogen element, the halogen element included in the halogenated material.

In accordance with still another aspect of the inventive concepts, a method of monitoring a semiconductor fabrication process includes removing a first layer pattern on a second layer pattern to expose the second layer pattern, the first and second layer patterns formed on a substrate, generating photoelectrons by irradiating X-rays to a surface of the substrate concurrently with or subsequent to the removing, and inferring at least one material existing on the surface of the substrate by collecting and analyzing the photoelectrons.

When the first layer pattern includes silicon and the second layer pattern includes a transition metal, the material existing on the surface of the substrate may include at least one of fluoride ions (F−) and a halogenated metal.

The transition metal includes titanium (Ti), and the halogenated metal may include titanium-fluorine (Ti—F).

The analyzing of the photoelectrons may include measuring at least one of intensities and binding energies of photoelectrons of 1s orbitals of halogen elements in the halogenated metal.

The method further includes determining that the removing does not completely remove the first layer pattern on the second layer pattern if the inferring determines that the material consists essentially of fluororide ions (F−).

The irradiating of the X-rays onto the surface of the wafer may include at lest one of moving the stage and scanning the surface of the wafer.

Details of other example embodiments are included in the detailed description and the drawings.

### BRIEF DESCRIPTION OF THE DRAWINGS

The foregoing and other features and advantages of the inventive concepts will be apparent from the more particular description of example embodiments of the inventive concepts, as illustrated in the accompanying drawings in which like reference characters refer to the like elements throughout. The drawings are not necessarily to scale, may not precisely reflect the precise structural or performance characteristics of any given example embodiment, and should not be interpreted as defining or limiting the range of values or properties encompassed by example embodiments. For example, the relative thicknesses and positioning of layers, regions and/or structural elements may be reduced or exaggerated for clarity to better illustrate and/or emphasize the inventive concepts. In the drawings:

FIG. 1 is a conceptual view illustrating a processing system in accordance with an example embodiment of the inventive concepts;

FIGS. 2A through 2I are cross-sectional views of a wafer for explaining a wafer fabrication process in accordance with an example embodiment of the inventive concepts;

FIG. 3A is a conceptual view illustrating a process of inspecting a surface of a wafer, in accordance with an example embodiment of the inventive concepts;

FIG. 3B is a view illustrating a wafer map showing results obtained after inspecting a surface of a wafer, in accordance with an example embodiment of the inventive concepts; and

FIGS. 4A through 4D are graphs showing spectra of photoelectrons generated from a surface of a wafer in response to irritated X-rays, collected by a photoelectron detector of a processing system, and analyzed by an analyzing unit of the processing system.

### DETAILED DESCRIPTION OF THE EMBODIMENTS

The inventive concepts will become more apparent through the following example embodiments and drawings. The example embodiments are provided so that this disclosure will be thorough and complete and will fully convey the scope of the inventive concepts to one of ordinary skill in the art. Accordingly, the inventive concepts may be embodied in many different forms and should not be construed as limited to the example embodiments set forth herein.

The terminology used herein is for the purpose of describing particular example embodiments only and is not intended to be limiting of the present inventive concepts. As used herein, the singular forms “a,” “an” and “the” are intended to include the plural forms as well, unless the context clearly indicates otherwise. It will be further understood that the terms “comprises” and/or “comprising,” when used in this specification, specify the presence of stated elements, steps, operations, and/or devices, but do not preclude the presence or addition of one or more other elements, steps, operations, and/or devices thereof.

Spatially relative terms, such as “beneath,” “below,” “lower,” “above,” “upper” and the like, may be used herein for ease of description to describe one device's or element's relationship to another device(s) or element(s) as illustrated in the figures. It will be understood that the spatially relative terms are intended to encompass different orientations of the device in use or operation in addition to the orientation depicted in the figures. For example, if the device in the figures is turned over, devices described as “below” or “beneath” other devices would then be oriented “above” the other devices. Thus, the term “below” can encompass both orientations of above and below. The device may be otherwise oriented and the spatially relative descriptors used herein may be interpreted accordingly.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Also, example embodiments are described herein with reference to cross-sectional illustrations and/or plan illustrations that are schematic illustrations of idealized example embodiments. In the drawings, thicknesses of films and regions are exaggerated for clarity. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an etched region illustrated as a rectangle will, typically, have rounded or curved features. Thus, the regions illustrated in the figures are schematic in nature and their shapes are not intended to illustrate the actual shapes of regions of a device and are not intended to limit the scope of the present inventive concepts. It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

The like reference numerals used herein denote the like elements throughout. Accordingly, even though the same or similar reference numerals are not mentioned or described in corresponding drawings, the same or similar reference numerals may be understood with reference to other drawings.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments of the present invention will be explained in further detail with reference to the accompanying drawings.

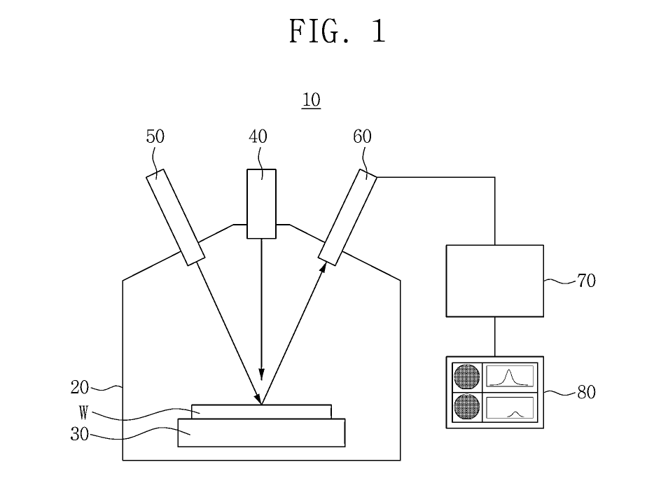

FIG. 1 is a conceptual view illustrating a processing system 10 in accordance with an example embodiment of the inventive concepts. Referring to FIG. 1, the processing system 10 includes a chamber 20, a stage 30 disposed in the chamber 20, a camera 40, an X-ray source 50, and a photoelectron detector 60 disposed over the chamber 20. The processing system 10 further includes an analyzing unit 70 and a display unit 80. The chamber 20 may have a sealed cylindrical shape that may maintain a vacuum state. The stage 30 may have a flat top surface on which a wafer W may be placed. The stage 30 may move horizontally. For example, the camera 40 may move horizontally in a X-direction and/or a Y-direction, the Y-direction being perpendicular to the X-direction. The camera 40 may obtain an optical image of the wafer W, or may provide, for example, position information of the wafer W, alignment information, etc. The X-ray source 50 may radiate X-rays onto the wafer W. The X-ray source 50 may irradiate X-rays onto a top surface of the wafer W in spots and/or shots. Photoelectrons may be generated on a surface of the wafer W onto which the X-rays are irradiated. The photoelectrons may be collected by the photoelectron detector 60. The collected photoelectrons may be analyzed by the analyzing unit 70. The analyzing unit 70 may quantitatively and qualitatively analyze intensities of the photoelectrons according to regions of the wafer W and may provide a wafer map or a graph. The analyzing unit 70 may include a microprocessor, for example, a server, a computer, etc. The display unit 80 may include a monitor. The display unit 80 may visually display, e.g., a wafer map, a photoelectron intensity spectrum, and/or a graph.

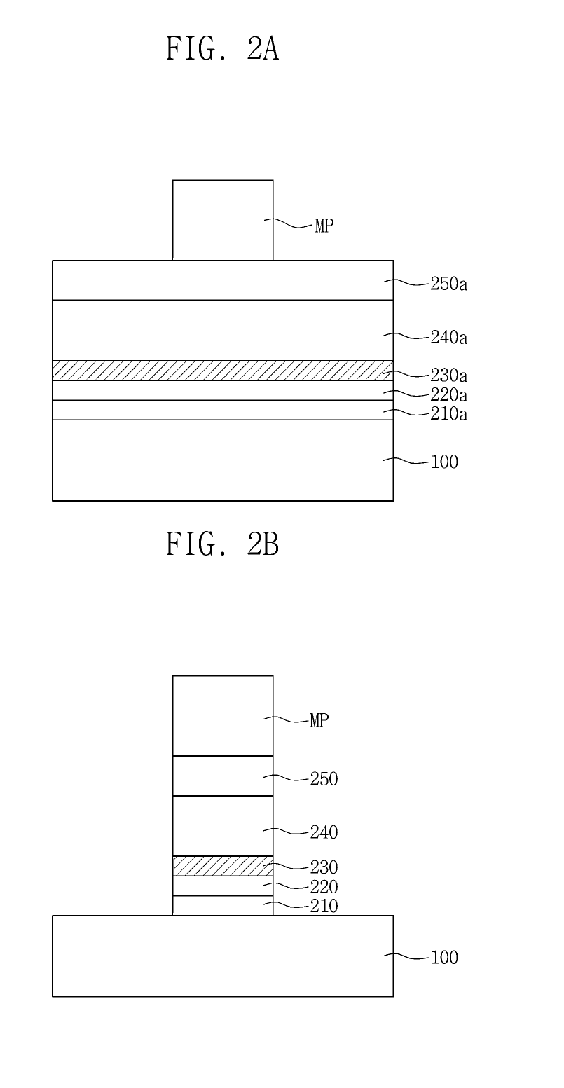

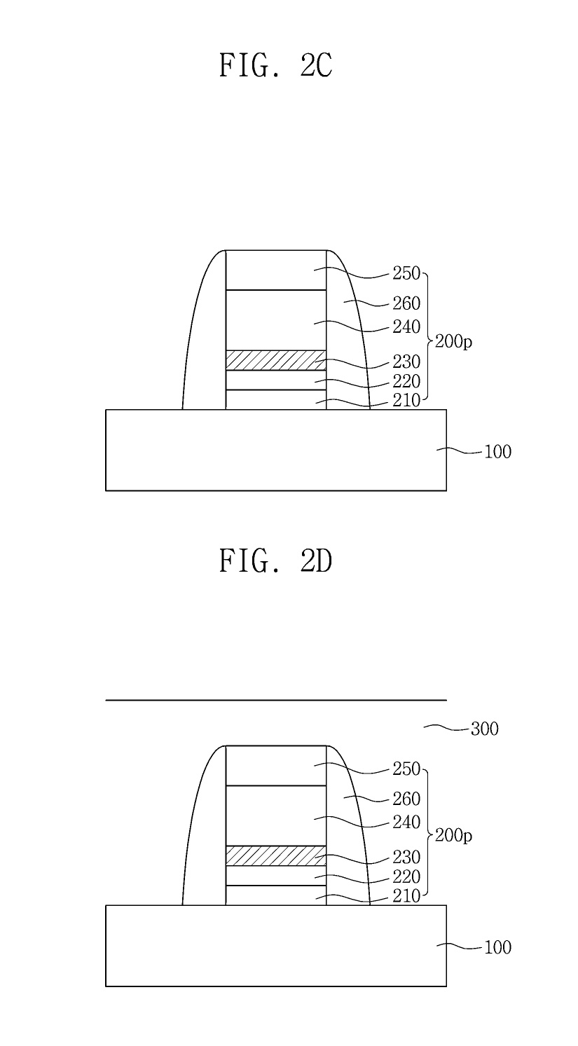

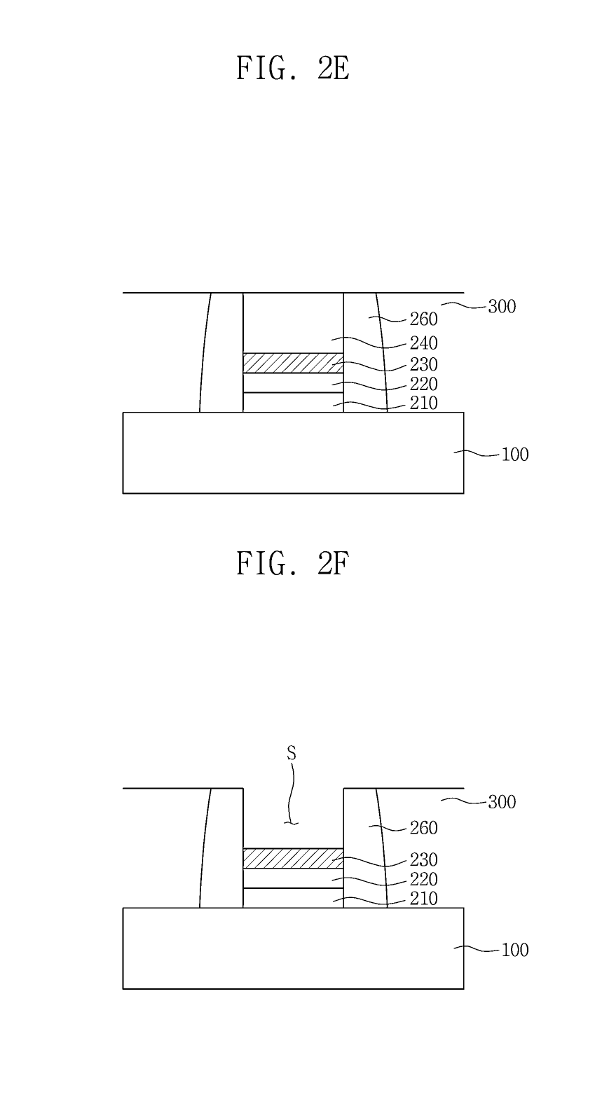

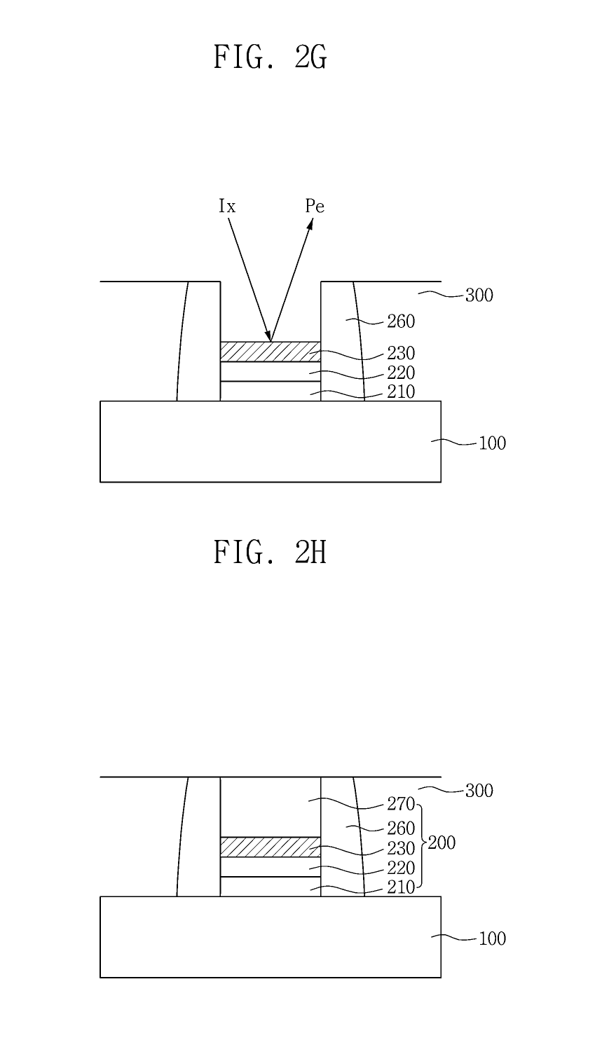

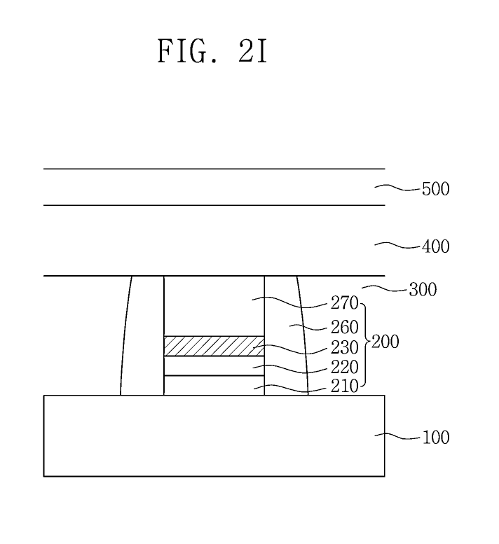

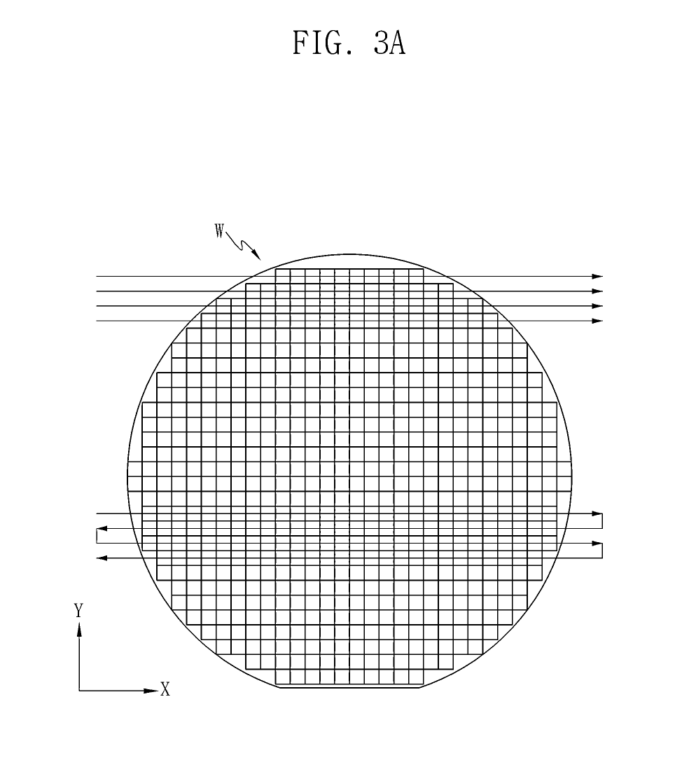

FIGS. 2A through 2I are cross-sectional views of a wafer for explaining a semiconductor fabrication process in accordance with an example embodiment of the inventive concepts.

Referring to FIG. 2A, the semiconductor fabrication process includes sequentially forming a buffer insulating layer 210a, a gate insulating layer 220a, a barrier layer 230a, a sacrificial layer 240a, and a sacrificial mask layer 250a on a substrate 100, and forming a mask pattern MP on the sacrificial mask layer 250a.

The substrate 100 may include, e.g., a bulk silicon wafer, a silicon-on-insulator (SOI) wafer, or a compound semiconductor wafer.

The buffer insulating layer 210a may include, e.g., an oxidized silicon layer or a silicon oxide layer. For example, the buffer insulating layer 210a may be formed by oxidizing a surface of the substrate 100 or depositing silicon oxide on the surface of the substrate 100.

The gate insulating layer 220a may have a dielectric constant or a work function higher than that of the buffer insulating layer 210a. For example, the gate insulating layer 210a may be formed by depositing metal oxide, e.g., hafnium oxide (HfO₂), lanthanum oxide (La₂O₃), aluminum oxide (Al₂O₃).

The barrier layer 230a may include, for example, at least one of titanium (Ti), titanium nitride (TiN), tantalum (Ta), tantalum nitride (TaN), vanadium (V), chromium (Cr), magnesium (Mg), iron (Fe), cobalt (Co), nickel (Ni), copper (Cu), zinc (Zn), other transition metals, other refractory metals, alloys thereof, and metal compounds thereof.

The sacrificial layer 240a may be formed by depositing amorphous or polycrystalline silicon.

The sacrificial mask layer 250a may include a material having an etch selectivity with respect to the sacrificial layer 240a. The sacrificial mask layer 250a may be formed by depositing a material that may be used as an etching mask on the sacrificial layer 240a, e.g., silicon nitride.

The mask pattern MP may include a photoresist that is formed by performing a photolithographic process.

Referring to FIG. 2B, the method includes sequentially etching the sacrificial mask layer 250a, the sacrificial layer 240a, the barrier layer 230a, the gate insulating layer 220a, and the buffer insulating layer 210a using the mask pattern MP as an etching mask to form a buffer insulating pattern 210, a gate insulating pattern 220, a barrier pattern 230, a sacrificial pattern 240, and a sacrificial mask pattern 250. Next, the mask pattern MP may be removed.

Referring to FIG. 2C, the method includes depositing a spacer material layer and performing an etch-back process to form a gate spacer 260 that covers the buffer insulating pattern 210, the gate insulating pattern 220, the barrier pattern 230, the sacrificial pattern 240, and the sacrificial mask pattern 250, thereby forming a preliminary gate structure 200p. For example, the gate spacer 260 may include, e.g., silicon nitride.

Referring to FIG. 2D, the method includes forming an interlayer insulating layer 300 that covers the preliminary gate structure 200p. The interlayer insulating layer 300 may include, e.g., silicon oxide.

Referring to FIG. 2E, the method includes performing a process of planarizing upper portions of the interlayer insulating layer 300 and the preliminary gate structure 200p to expose a top surface of the sacrificial pattern 240. For example, the planarization process may planarized and remove the sacrificial mask pattern 250, an upper portion of the gate spacer 260, and/or an upper portion of the interlayer insulating layer 300.

Referring to FIG. 2F, the method includes removing the sacrificial pattern 240 to form an electrode space S. The removing of the sacrificial pattern 240 may include performing a dry etching process using halide gases including fluoride ions (F⁻) or chloride ions (Cl⁻) such as SF₆, CF₄, CHF₃, or CCl₄, and/or performing a wet etching process using chemicals including HF.

Referring to FIG. 2G, the method includes inspecting and analyzing a surface of the barrier pattern 230 using X-ray photoelectron spectroscopy (XPS). For example, further referring to FIG. 1, the inspecting includes irradiating X-rays 1x onto the surface of the barrier pattern 230 using the X-ray source 50 and detecting photoelectrons Pe generated from the surface of the barrier pattern 230 using the photoelectron detector 60.

The photoelectrons Pe may provide information about binding energies of materials existing on the surface of the barrier pattern 230. For example, the photoelectrons Pe may have, e.g., binding energies of is orbital of halogen elements.

Binding energies of is orbital when halogen elements independently exist (e.g., when physisorption occurs on the surface of the barrier pattern 230 or on a surface of the sacrificial pattern 240) and binding energies of is orbital when halogen elements bond to materials included in the barrier pattern 230 (e.g., when chemisorption occurs on the surface of the barrier pattern 230) are different from each other according to whether a chemical shift occurs. Accordingly, types and amounts of materials existing on the surface of the barrier pattern 230 may be inferred by measuring intensities or doses according to binding energies of is orbitals of the photoelectrons Pe. For example, the types of material may be, e.g., a compound type or an ion type of F.

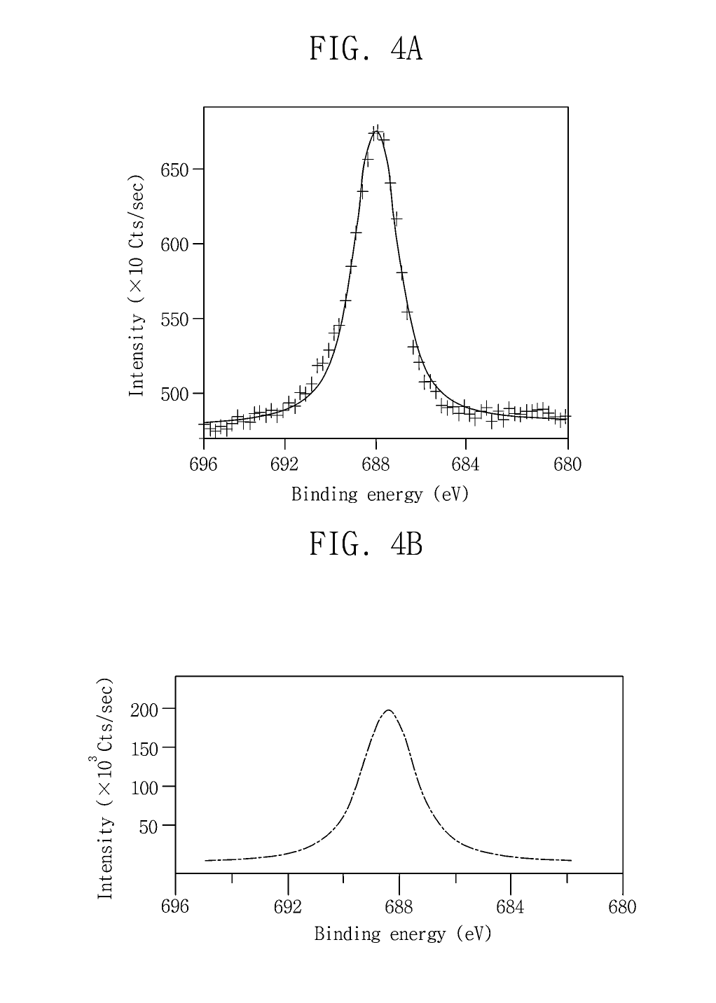

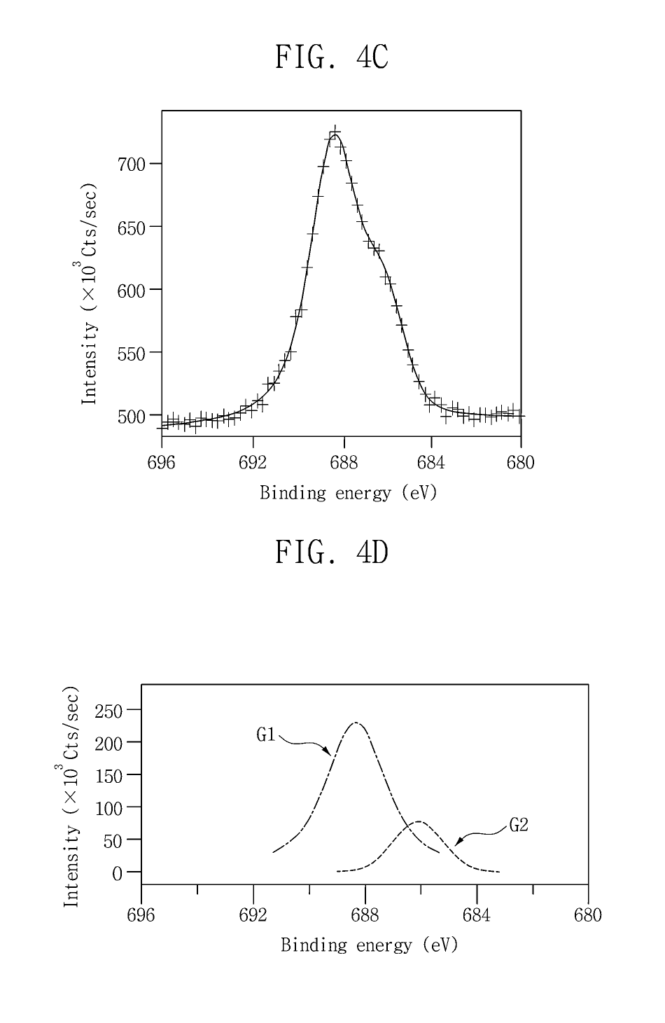

In detail, when the sacrificial pattern 240 includes silicon (Si) and the barrier pattern 230 includes titanium (Ti), any one or both of fluoride ions (F⁻) and a Ti—F compound may exist on the surface of the barrier pattern 230. Accordingly, the photoelectrons Pe may have any one or both of binding energy of 1s orbitals of the fluoride ions (F⁻) and binding energy of 1s orbitals of fluorine (F⁻) of the Ti—F compound. Accordingly, amounts of the fluoride ions (F⁻) and the Ti—F compound existing on the barrier pattern 230 may be measured by analyzing doses or an intensities according to binding energy of 1s orbitals of the photoelectrons Pe. A detailed explanation thereof will be given below with reference to FIGS. 4A through 4D.

Referring to FIG. 2H, the method includes forming a gate electrode 270 in the electrode space S to form a gate structure 200. The forming of the gate electrode 270 may include forming a metal layer in the electrode space S and on the interlayer insulating layer 300 and performing a planarization process such as chemical-mechanical polishing (CMP) to equalize heights of uppermost ends of the gate spacer 260 and the metal layer such that the metal layer is confined in the electrode space S.

Referring to FIG. 2I, the method includes forming a capping insulating layer 400 and a stopper layer 500 on the gate electrode 270 and the interlayer insulating layer 300. The capping insulating layer 400 may be formed by depositing, e.g., silicon oxide, and the stopper layer 500 may be formed by depositing, e.g., silicon nitride.

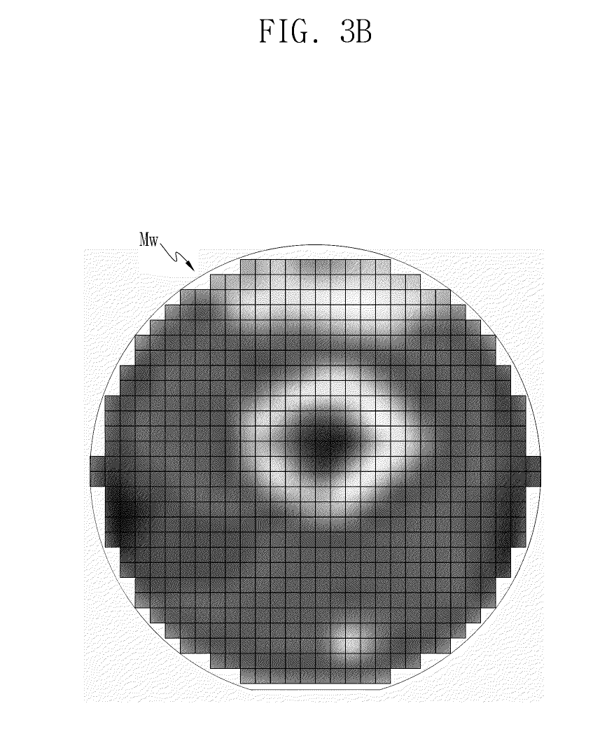

FIG. 3A is a conceptual view illustrating a process of inspecting a surface of the wafer W, in accordance with an example embodiment of the inventive concepts. Referring to FIG. 3A, the method includes scanning the surface of the wafer W using the X-ray source 50, e.g., in one direction or in both directions. Further referring to FIG. 1, the scanning may include moving the stage 300 in the X-direction and/or the Y-direction.

FIG. 3B is a view illustrating a wafer map Mw showing results obtained after inspecting the surface of the wafer W, in accordance with an example embodiment of the inventive concepts. Referring to FIG. 3B, the wafer map Mw shows various photoelectron analysis spectra according to characteristics of materials existing on the surface of the wafer W. For example, the wafer map Mw shows various spectra according to types and ratios of halogenated materials existing on the surface of the wafer W. Accordingly, the wafer map Mw may provide information about effects on processes, defect factors in the processes, and trends of the processes according to various regions of the wafer W.

FIGS. 4A through 4D are graphs showing collected and analyzed photoelectron spectra when considerable amounts of two materials exist on the surface of the wafer W. The X-axis represents binding energies of photoelectrons of materials existing on the surface of the wafer W, and the Y-axis represents intensities of the collected photoelectrons. For example, after X-rays are irradiated onto the wafer W, intensities of photoelectrons having information about binding energies of is orbitals of halogen elements of halogen ions or a compound existing on the surface of the wafer W may be shown. The expression “considerable amounts” may refer to amounts equal to or greater than at least 500E3 Cts/sec.

FIGS. 4B and 4D show results obtained after removing backgrounds from FIGS. 4A and 4C. For example, an intensity less than 500E3 Cts/sec is removed by assuming that 500E3 Cts/sec is 0 (zero). Accordingly, spectra of relatively remarkable amounts of photoelectrons, e.g., amounts of photoelectrons exceeding 500E3 Cts/sec, may be shown.

Referring to FIGS. 4A and 4B, the collected and analyzed photoelectron spectrum shows only one peak intensity at binding energy of about 688 eV. Thus, further referring to FIG. 2G, it may be inferred that only fluoride ions (F⁻) exist on the surface of the wafer W or the surface of the barrier pattern 230. Accordingly, it also may be inferred that the sacrificial pattern 240 still remains on the surface of the barrier pattern 230. Referring to FIG. 4A, the collected and analyzed photoelectron spectrum in accordance with an example embodiment of the inventive concept smay have a Gaussian distribution.

Referring to FIG. 4B, the collected and analyzed photoelectron spectrum in accordance with an example embodiment of the inventive concepts shows only one peak intensity at binding energy of about 688 eV. Accordingly, further referring to FIG. 2G, it may be inferred that only fluoride ions (F⁻) exist on the surface of the wafer W or the surface of the sacrificial pattern 240.

Referring to FIG. 4C, the collected and analyzed photoelectron spectrum in accordance with an example embodiment of the inventive concepts may have a Gaussian distribution. For example, photoelectrons generated in materials having binding energy of about 688 eV may be collected.

Referring to FIG. 4D, from the collected and analyzed photoelectron spectrum, a first intensity graph G1, a peak of which corresponds to the number of photoelectrons having binding energy of about 688 eV, and a second intensity graph G2, a peak of which corresponds to the number of photoelectrons having binding energy of about 686 eV, may be analyzed, separated, or extracted. Because the peak of the first intensity graph G1 is about 230E3 Cts/sec (cts=counts) and the peak of the second intensity graph G2 is about 150E3 Cts/sec, it may be inferred that materials having binding energy of 688 eV existing on the surface of the wafer Ware about 1.5 times or more greater than materials having binding energy of 686 eV existing on the surface of the wafer W.

Further referring to FIG. 2G, when X-rays are irradiated onto the surface of the wafer W, on which the barrier pattern 230 is exposed, photoelectrons having various binding energies may be generated from the surface of the wafer W. Photoelectrons may be generated from halogenated materials including materials in the barrier pattern 230 and halogen ions. For example, when halogen ions include fluoride ions (F⁻) and binding energy of is orbitals of the fluoride ions (F⁻) is about 688 eV, the first intensity graph G1 of FIG. 4D may provide results obtained after quantitatively and qualitatively analyzing the fluoride ions (F⁻) existing on the surface of the wafer W or the surface of the barrier pattern 230. Further, when the barrier pattern 230 includes titanium (Ti) and binding energy of is orbitals of fluorine (F⁻) atoms of a metal compound having Ti—F bonding is about 686 eV, the second intensity graph G2 of FIG. 4D may provide results obtained after quantitatively and qualitatively analyzing the Ti—F metal compound existing on the surface of the wafer W or the surface of the barrier pattern 230. Referring back to FIGS. 4C and 2G, it may be inferred that both the fluoride ions (F⁻) (physisorption) and the Ti—F bonding in the metal compound exist on the surface of the barrier pattern 230. Accordingly, it may be inferred that the sacrificial pattern 240 on the surface of the wafer W or the surface of the barrier pattern 230 is substantially completely removed.

Referring back to FIGS. 4A through 4D, when only the fluoride ions (F⁻) exist on the barrier pattern 230, it may be determined that a process of removing the sacrificial pattern 240 is not sufficiently performed. When both the fluoride ions (F⁻) and the Ti—F compound exist on the barrier pattern 230, it may be determined that a process of removing the sacrificial pattern 240 is sufficiently performed or excessively performed. An process condition for the process of removing the sacrificial pattern 240 may be adjusted in consideration of FIGS. 4A through 4D.

As can be seen from the foregoing, a method of monitoring a semiconductor fabrication process using XPS in accordance with the inventive concepts may have a higher resolution than an optical monitoring method or an electron beam monitoring method. Thus, the monitoring method in accordance with the inventive concepts can monitor process status more precisely.

The monitoring methods in accordance with the inventive concepts may monitor non-particle defects, which the optical monitoring method or the electron beam monitoring method may not detect.

The monitoring methods in accordance with the inventive concepts may provide a wafer map according to a process state.

Because the monitoring methods in accordance with the inventive concepts may provide information about a chemical bonding state of a surface of a sample, the monitoring methods in accordance with the inventive concepts may monitor existences of various types of materials and may provide precise analysis results.

Other un-mentioned effects of the inventive concepts will be apparent in the detailed description.

Although a few example embodiments have been described, those skilled in the art will readily appreciate that many modifications are possible in example embodiments without materially departing from the novel teachings and advantages of the inventive concepts. Accordingly, all such modifications are intended to be included within the scope of these inventive concepts as defined in the claims. Therefore, it is to be understood that the foregoing is illustrative of various example embodiments and is not to be construed as limited to the specific embodiments disclosed herein, and that modifications to the disclosed example embodiments, as well as other example embodiments, are intended to be included within the scope of the appended claims.

What is claimed is:

1. A method of monitoring a semiconductor fabrication process, the method comprising:
forming a barrier pattern on a substrate;
forming a sacrificial pattern on the barrier pattern;
removing the sacrificial pattern to expose a surface of the barrier pattern;
generating photoelectrons by irradiating X-rays to a surface of the substrate; and
inferring at least one material existing on the surface of the substrate by collecting and analyzing the photoelectrons.

2. The method of claim 1, wherein when the sacrificial pattern includes silicon and the barrier pattern includes a transition metal, the material existing on the surface of the substrate includes at least one of fluoride ions (F⁻) and a halogenated metal.

3. The method of claim 2, wherein the transition metal includes titanium (Ti), and the halogenated metal includes titanium-fluorine (Ti—F).

4. The method of claim 3, wherein the analyzing of the photoelectrons includes measuring intensities of photoelectrons of 1s orbitals of halogen elements in the halogenated metal.

5. The method of claim 3, wherein the analyzing of the photoelectrons includes measuring binding energies of photoelectrons of is orbitals of halogen elements in the halogenated metal.

6. The method of claim 3, wherein when the inferring determines that the material consists essentially of the fluoride ions (F⁻), the inferring further determines that the removing does not completely remove the sacrificial pattern on the barrier pattern.

7. The method of claim 3, wherein when the inferring determines that the material includes the fluoride ions (F⁻) and a Ti—F compound, the inferring further determines that the removing substantially completely removes the sacrificial pattern on the barrier pattern.

8. The method of claim 1, wherein the analyzing of the photoelectrons comprises:
obtaining intensity spectra of the collected photoelectrons; and
separating the intensity spectra into at least one individual intensity spectrum according to binding energies of the photoelectrons.

9. The method of claim 8, wherein the binding energies are binding energies of 1s orbital of the material existing on the surface of the substrate.

10. The method of claim 1, before the forming of the barrier pattern, the method further comprising:
forming a buffer insulating pattern on the substrate; and
forming a gate insulating pattern on the buffer insulating pattern.

11. The method of claim 10, wherein the buffer insulating pattern includes oxidized silicon, and the gate insulating pattern includes metal oxide.

12. The method of claim 10, after the forming of the sacrificial pattern, the method further comprising:
forming a gate spacer that covers a top surface of the sacrificial pattern, side surfaces of the buffer insulating pattern, the gate insulating pattern, the barrier pattern, and the sacrificial pattern; and
exposing the top surface of the sacrificial pattern by removing the gate spacer that covers the top surface of the sacrificial pattern.

13. The method of claim 12, wherein
the gate spacer includes silicon nitride, and
the removing of the gate spacer includes performing a chemical-mechanical polishing (CMP) process.

14. A method of monitoring a semiconductor fabrication process, the method comprising:
introducing a wafer onto a stage of a processing system, a surface of the wafer having at least one halogenated material thereon, the processing system including a chamber, a stage disposed in the chamber, an X-ray source, and a photoelectron detector disposed over the chamber;
irradiating X-rays onto the surface of the wafer on the stage using the X-ray source;
collecting photoelectrons generated by the halogenated material on the surface of the wafer using the photoelectron detector; and
inferring the halogenated material existing on the surface of the wafer by analyzing the collected photoelectrons according to binding energies of 1s orbitals of at least one halogen element, the halogen element included in the halogenated material.

15. The method of claim 14, wherein the irradiating of the X-rays onto the surface of the wafer includes at least one of moving the stage and scanning the surface of the wafer.

16. A method of monitoring a semiconductor fabrication process, the method comprising:
removing a first layer pattern on a second layer pattern to expose the second layer pattern, the first and second layer patterns formed on a substrate;
generating photoelectrons by irradiating X-rays to a surface of the substrate concurrently with or subsequent to the removing; and
inferring at least one material existing on the surface of the substrate by collecting and analyzing the photoelectrons.

17. The method of claim 16, wherein when the first layer pattern includes silicon and the second layer pattern includes a transition metal, the material existing on the surface of the substrate includes at least one of fluoride ions (F⁻) and a halogenated metal.

18. The method of claim 17, wherein the transition metal includes titanium (Ti), and the halogenated metal includes titanium-fluorine (Ti—F).

19. The method of claim 17, wherein the analyzing of the photoelectrons includes measuring at least one of intensities and binding energies of photoelectrons of 1s orbitals of halogen elements in the halogenated metal.

20. The method of claim 17, further comprising:
determining that the removing does not completely remove the first layer pattern on the second layer pattern if the inferring determines that the material consists essentially of fluoride ions (F−).
